(19) United States
(12) Patent Application Publication
(10) Pub. No.: US 2002/0036348 A1
(43) Pub. Date: Mar. 28, 2002

(54) Semiconductor device having multi-layered wiring structure

(75) Inventors: Noriaki Matsunaga, Chigasaki-shi (JP); Hideki Shibata, Yokohama-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 09/961,098

(22) Filed: Sep. 24, 2001

(30) Foreign Application Priority Data
Sep. 26, 2000 (JP) 2000-292640

(51) Int. Cl. H01L 23/48; H01L 23/52; H01L 29/40

(52) U.S. Cl. 257/758

(57) ABSTRACT

A semiconductor device comprises a first interlayer insulating film, a first wiring, a cap film, a second interlayer insulating film, a second wiring, and a barrier metal film. The first interlayer insulating film is formed on a semiconductor substrate. The first wiring is buried in the first interlayer insulating film and is in contact with the first interlayer insulating film. The cap film is formed on the first wiring. The second interlayer insulating film is formed on the cap film. A selectivity ratio can be obtained between the second interlayer insulating film and the cap film in the etching step. The second wiring is buried in the second interlayer insulating film. The barrier metal film is formed between the second wiring and the second interlayer insulating film. Further, the barrier metal film prevents the material constituting the second wiring from being diffused into the second interlayer insulating film.

### CROSS-REFERENCE TO RELATED APPLICATIONS

This application is based upon and claims the benefit of priority from the prior Japanese Patent Application No. 2000-292640, filed Sep. 26, 2000, the entire contents of which are incorporated herein by reference.

### BACKGROUND OF THE INVENTION

1. Field of the Invention

The present invention relates to a semiconductor device having a multi-layered wiring structure.

2. Description of the Related Art

Let us describe a conventional semiconductor device having a multi-layered wiring structure prepared by forming a plurality of layer wirings each containing copper as a main wiring material one upon the other with an interlayer insulating film interposed therebetween.

FIG. 1 is a cross sectional view showing a conventional semiconductor device having a multi-layered wiring structure.

As shown in FIG. 1, a first layer wiring 111, a second layer wiring 112, a third layer wiring 113, a fourth layer wiring 114, a fifth layer wiring 115 and a sixth layer wiring 116 are formed one upon the other in the order mentioned on a semiconductor substrate 101. A first interlayer insulating film 121 is formed between the semiconductor substrate 101 and the first layer wiring 111. Further, a second interlayer insulating film 122 is formed between the first layer wiring 111 and the second layer wiring 112, a third interlayer insulating film 123 is formed between the second layer wiring 112 and the third layer wiring 113, a fourth interlayer insulating film 124 is formed between the third layer wiring 113 and the fourth layer wiring 114, a fifth interlayer insulating film 125 is formed between the fourth layer wiring 114 and the fifth layer wiring 115, and a sixth interlayer insulating film 126 is formed between the fifth layer wiring 115 and the sixth layer wiring 116.

Further, a barrier metal or a liner material layer 131 (hereinafter referred to as a barrier metal film 131) is formed between the first layer wiring 111 and the first interlayer insulating film 121. Likewise, a barrier metal film 132 is formed between the second layer wiring 112 and the second interlayer insulating film 122, a barrier metal film 133 is formed between the third layer wiring 113 and the third interlayer insulating film 123, a barrier metal film 134 is formed between the fourth layer wiring 114 and the fourth interlayer insulating film 124, a barrier metal film 135 is formed between the fifth layer wiring 115 and the fifth interlayer insulating film 125, and a barrier metal film 136 is formed between the sixth layer wiring 116 and the sixth interlayer insulating film 126. These barrier metal films serve to prevent Cu used as the wiring material from being diffused within the interlayer insulating film. Further, the barrier metal films serve to facilitate the flow of Cu into the groove formed in the interlayer insulating film when Cu is buried in the groove.

Further, cap layers 141 to 146 are formed on the upper surfaces of the first to sixth layer wirings 111 to 116, respectively. These cap layers serve to prevent Cu used as the wiring material from being diffused into the interlayer insulating film from the upper surface on which the barrier metal film is not formed.

In the conventional damascene wiring in which Cu is used as a main wiring material, it is necessary to form the barrier layers 131 to 136 as shown in FIG. 1. In the Cu wiring used nowadays, the barrier metal film is of a single layer structure or a laminate structure formed of a plurality of layers each formed of tantalum, titanium, tungsten, a nitride thereof, or a ternary compound further containing silicon and has a thickness of about 10 nm to 15 nm. In view of the restriction in terms of the continuity as a film and the guarantee of the barrier function, it is difficult to decrease the thickness of the barrier metal film.

Nowadays, the wiring is made finer and finer. However, since it is difficult to decrease the thickness of the barrier metal film as described above, the rate of the area occupied by the barrier metal film in the cross section of the wiring is rendered high with progress in the fineness of the wiring. As a result, a problem is generated that the effective resistance of the wiring is rendered high because the barrier metal has a resistivity higher than that of the wiring material.

In addition to the progress in the fineness of the wiring, it is also required to decrease the thickness of the wiring. This is because it is necessary to prevent the capacitance between adjacent wirings in the same layer from being increased in accordance with miniaturization, particularly, the decrease in the distance between the adjacent wirings. Where the wiring width and the distance between adjacent wirings are set equal to each other, it is desirable for the ratio of the wiring height (film thickness) to the wiring width, i.e., the ratio of height/width, to be at about 1 or less. For example, where the wiring has a width of 0.1 μm, it is desirable for the height of the wiring to be not larger than 0.1 μm.

Where the wiring is made finer, a serious problem is generated as follows. As described previously, a barrier metal film is used in the case of a Cu wiring in order to prevent Cu from being diffused into the insulating film. However, the barrier metal film is not formed on the upper surface of the Cu wiring. Therefore, in the Cu wiring employed nowadays, an insulating film capable of suppressing the Cu diffusion is deposited on the upper surface of the Cu wiring so as to suppress the Cu diffusion. The cap film used as a film for suppressing the Cu diffusion includes, for example, an insulating film consisting essentially of silicon nitride (hereinafter referred to as a silicon nitride film) and an insulating film consisting essentially of silicon carbide (hereinafter referred to as a silicon carbide film). In many cases, the silicon carbide film actually used contain in general hydrogen (H), oxygen (O) and nitrogen (N). As a result, the silicon nitride film and the silicon carbide film have a relative high relative dielectric constant. Specifically, the silicon nitride film has a dielectric constant ε of about 7 in the highest case, and the silicon carbide film has a dielectric constant ε of about 5 in the highest case.

In order to decrease the capacitance between the adjacent wirings, an insulating film having a low dielectric constant, i.e., a dielectric constant of 3 or less, is used as the interlayer insulating film. However, a silicon nitride film or a silicon carbide film having a relatively high dielectric constant is used as the cap film serving to suppress the Cu diffusion. As a result, the capacitance between the wirings within the same layer or between the wirings of different layers is rendered effectively high under the influence given by the dielectric constant of the cap film. It should be noted that the influence given by the dielectric constant of the cap film serving to suppress the Cu diffusion is rendered prominent with decrease in the thickness of the wiring.

### BRIEF SUMMARY OF THE INVENTION

A semiconductor device According to an aspect of the present invention comprises a first interlayer insulating film formed on a semiconductor substrate; a first wiring buried in the first interlayer insulating film in contact with the first interlayer insulating film; a cap film formed on the first wiring; a second interlayer insulating film formed on the cap film, a selectivity ratio being obtained between the second interlayer insulating film and the cap film in the etching step; a second wiring buried in the second interlayer insulating film; and a barrier metal film formed between the second wiring and the second interlayer insulating film and serving to prevent the material forming the second wiring from being diffused into the second interlayer insulating film.

### BRIEF DESCRIPTION OF THE SEVERAL VIEWS OF THE DRAWING

FIG. 1 is a cross sectional view showing the construction of a conventional semiconductor device having a multi-wiring structure;

FIG. 2 is a cross sectional view showing the construction of a semiconductor device having a multi-wiring structure according to a first embodiment of the present invention;

FIG. 3A is a graph showing the change in the LSI performance in the case where the resistivity of the first layer wiring is changed in a semiconductor device having first to fifth layer wirings according to the embodiment of the present invention;

FIG. 3B is a table showing the wiring size and the average wiring length of the first to fifth layer wirings of the semiconductor device according to the embodiment of the present invention;

FIG. 3C is a cross sectional view showing the measuring portions of the wiring size shown in FIG. 3B;

FIG. 4 is a cross sectional view showing the construction of a semiconductor device having a multi-wiring structure according to a second embodiment of the present invention;

FIG. 5 is a cross sectional view showing the construction of a semiconductor device having a multi-wiring structure according to a third embodiment of the present invention;

FIG. 6 is a cross sectional view showing the construction of a semiconductor device having a multi-wiring structure according to a fourth embodiment of the present invention;

FIG. 7 is a cross sectional view showing the construction of a semiconductor device having a multi-wiring structure according to a fifth embodiment of the present invention;

FIG. 8 is a cross sectional view showing the construction of a semiconductor device having a multi-wiring structure according to a sixth embodiment of the present invention; and

FIG. 9 is a cross sectional view showing the construction of a semiconductor device having a multi-wiring structure according to a seventh embodiment of the present invention.

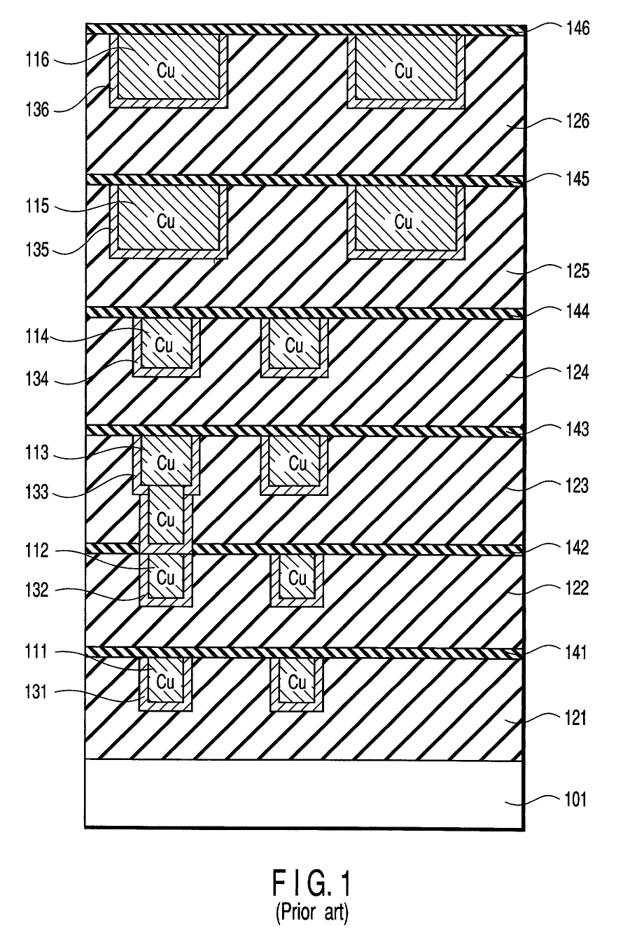

### DETAILED DESCRIPTION OF THE INVENTION

Some embodiments of the present invention will now be described with reference to the accompanying drawings.

First Embodiment

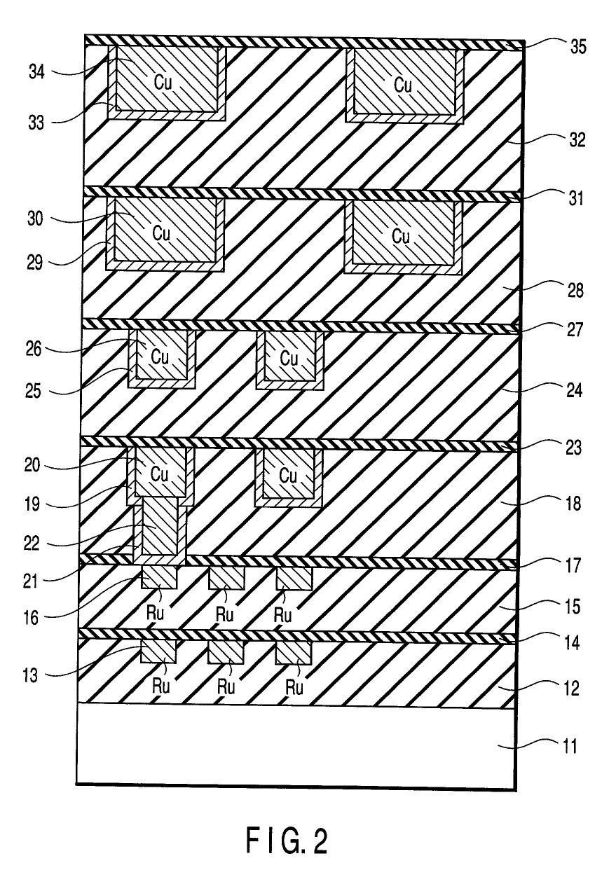

FIG. 2 is a cross sectional view showing the construction of a semiconductor device having a multi-wiring structure according to a first embodiment of the present invention.

As shown in FIG. 2, a first interlayer insulating film 12 is formed on a semiconductor substrate 11. A first layer wiring 13, which is not equipped with a barrier metal film, is formed within the first interlayer insulating film 12. The first layer wiring 13 is a damascene wiring. The first layer wiring 13, which is not covered with a barrier metal film, is buried in a wiring groove formed in the first interlayer insulating film 12 such that the material of the first layer wiring, e.g., ruthenium (Ru), is in direct contact with the first interlayer insulating film 12. The first interlayer insulating film 12 is an insulating film formed mainly of a silicon oxide film. The insulating film formed mainly of a silicon oxide film has a relative dielectric constant of about 4.1. The first layer wiring 13 is formed of, for example, ruthenium (Ru) as described above. The Ru layer is formed by a sputtering method.

The diffusion rate of Ru used as a wiring material into the first interlayer insulating film 12 is negligibly low. Also, the Ru layer can be easily buried within the wiring groove formed in the first interlayer insulating film. Therefore, it is unnecessary to form a barrier metal film on the side wall and the bottom wall of the wiring groove formed in the first interlayer insulating film 12. Incidentally, the barrier metal film, which is formed in general on the side wall and the bottom wall of the wiring groove formed in the interlayer insulating layer, serves to prevent the wiring material from being diffused into the interlayer insulating film. The barrier metal film also serves to facilitate the flow of the wiring material into the wiring groove formed in the interlayer insulating layer.

The first layer wiring 13 is a flat wiring having a ratio of the wiring height (film thickness) to the wiring width, i.e., an aspect ratio height/width, not larger than 1 because the capacitance between the adjacent wirings is small and the noise between the adjacent wirings is small. For example, the wiring width is not larger than 0.1 μm and the wiring height is also not larger than 0.1 μm. Further, the first layer wiring 13, which is a local wiring, has a wiring length not longer than about 10 μm.

A cap film 14 is formed on the first interlayer insulating film 12 and the first layer wiring 13. The cap film 14 is, for example, an insulating film formed mainly of, for example, silicon nitride or an insulating film formed mainly of silicon carbide. In general, it is necessary to form the cap film as a diffusion suppressing film on the upper surface of the Cu wiring. If the wiring is formed of Ru as in the first embodiment of the present invention, it is unnecessary to form the cap layer because the wiring material of Ru is not diffused into the interlayer insulating film. However, an etching stopper is required when a via hole is formed by a RIE method in the interlayer insulating film on the wiring. The cap film 14 formed on the first interlayer insulating film 12 and the first layer wiring 13 is a film acting substantially as an etching stopper.

Further, a second interlayer insulating film 15 is formed on the cap film 14. A second layer wiring 16, which is not provided with a barrier metal film, is formed within the second interlayer insulating film 15. The second layer wiring 16 is a damascene film like the first layer wiring 13. The second wiring layer 16, which is not provided with a barrier metal film, is buried in a wiring groove formed in the second interlayer insulating film 15 such that the material of the second layer wiring 16 is in direct contact with the second interlayer insulating film 15. The second interlayer insulating film 15 is an insulating film formed mainly of a silicon oxide film. Ruthenium (Ru) is used as a material of the second layer wiring 16 as described previously. The Ru layer is deposited by a sputtering method.

The second layer wiring 16 is a flat wiring having a ratio of the wiring height (film thickness) to the wiring width, i.e., an aspect ratio height/width, not larger than 1 because the capacitance between the adjacent wirings is small and the noise between the adjacent wirings is small. For example, the wiring width is not larger than 0.1 μm and the wiring height is also not larger than 0.1 μm. Further, the second layer wiring 16, which is a local wiring, has a wiring length not longer than about 10 μm.

A cap film 17 is formed on the second interlayer insulating film 15 and the second layer wiring 16. The cap film 17 consists of, for example, a silicon nitride film or a silicon carbide film and acts as an etching film like the cap film 14 described previously.

Further, a third interlayer insulating film 18 is formed on the cap film 17. A third layer wiring 20 covered with a barrier metal film 19 is formed in the third interlayer insulating film 18. The third layer wiring 20 is a damascene wiring. A contact plug 22 covered with the barrier metal film 21 is formed between the third layer wiring 20 and the second layer wiring 16. The contact plug 22 serves to permit the third layer wiring 20 to be electrically connected to the second layer wiring 16. The third interlayer insulating film 18 is an insulating film formed mainly of a silicon nitride film.

Copper (Cu) is used as the material of the third layer wiring 20. Copper is also used as the material of the contact plug 22. The copper layer is formed by a sputtering method, a plating method, a CVD method or a combination thereof. On the other hand, each of the barrier metal films 19 and 21 is formed of a film containing any of a tantalum nitride film, tantalum, titanium nitride, and tungsten nitride as a main component. These barrier metal films 19, 21 are formed by a sputtering method. Incidentally, the third layer wiring 20 has a wiring width not larger than 0.1 μm.

The contact plug 22 and the third layer wiring 20 are formed as follows. Specifically, after deposition of the third interlayer insulating film 18, a contact hole is formed in the third interlayer insulating film 18 such that the surface of the second wiring layer 16 is exposed to the outside. The barrier metal film 21 is formed on the inner surface of the contact hole, followed by burying Cu in the contact hole having the inner surface covered with the barrier metal film 21. The copper layer thus buried forms the contact plug 22.

In the next step, an additional third interlayer insulating film 18 is deposited on the contact plug 22 and the third interlayer insulating film 18, and a wiring groove is formed in the newly deposited third interlayer insulating film 18 such that the surface of the contact plug 22 is exposed to the outside. Then, the barrier metal film 19 is formed on the inner surface of the wiring groove, followed by burying Cu in the wiring groove having the inner surface covered with the barrier metal film 19. The copper layer thus buried in the wiring groove forms the third layer wiring 20.

Where the contact plug 22 is not connected to the third layer wiring 20, the third layer wiring 20 is formed as follows. Specifically, after deposition of the third interlayer insulating film 18, a wiring groove is formed in the third interlayer insulating film 18, followed by forming the barrier metal film 19 on the inner surface of the wiring groove. Further, a Cu layer is buried in the wiring groove having the inner surface covered with the barrier metal film 19. Incidentally, it is possible for each of the contact plug 22 and the third layer wiring 20 to be of a dual damascene structure. Where each of the contact plug 22 and the third layer wiring 20 is formed in the dual damascene structure, the barrier metal films 21, 19 are formed simultaneously in the contact hole and the wiring groove formed in the third interlayer insulating film 18, followed by simultaneously burying the barrier metal films 21, 19 in the contact hole and the wiring groove, respectively.

A cap film 23 is formed on the third interlayer insulating film 18 and the third layer wiring 20. The cap film 23 is formed of, for example, a silicon nitride film or a silicon carbide film. Where the third layer wiring 20 is formed of a Cu wiring, it is necessary to form a film capable of suppressing the Cu diffusion on the Cu wiring. The cap film 23 acts as a diffusion suppressing film for suppressing the diffusion of Cu forming the third layer wiring 20. The cap film 23 also acts as an etching stopper in the step of etching the interlayer insulating film on the third layer wiring 20.

Further, a fourth interlayer insulating film 24 is formed on the cap film 23. A fourth layer wiring 26 covered with a barrier metal film 25 is formed in the fourth interlayer insulating film 24. The fourth layer wiring 26 is a damascene wiring. The barrier metal film 25 is formed on the inner surface of the wiring groove formed in the fourth interlayer insulating film 24. A Cu layer is buried in the wiring groove having the inner surface covered with the barrier metal film 25 so as to form the fourth layer wiring 26. Incidentally, the wiring width of the fourth layer wiring 26 is not larger than 0.1 μm. The fourth interlayer insulating film 24 is an insulating film formed mainly of a silicon oxide film.

A cap film 27 is formed on the fourth interlayer insulating film 24 and the fourth layer wiring 26. The cap film 27 is formed of, for example, a silicon nitride film or a silicon carbide film. The cap film 27 on the fourth interlayer insulating film 24 and the fourth layer wiring 26 is a film acting as both the Cu diffusion suppressing film and the etching stopper like the cap film 23 described previously.

Further, a fifth interlayer insulating film 28 is formed on the cap film 27. A fifth layer wiring 30 covered with a barrier metal film 29 is formed in the fifth interlayer insulating film 28. The fifth layer wiring 30 is a damascene wiring. A barrier metal film 29 is formed on the inner surface of a wiring groove formed in the fifth interlayer insulating film 28. A Cu layer is buried in the wiring groove having the inner surface covered with the barrier metal film 29 so as to form the fifth layer wiring 30. Incidentally, the fifth layer wiring 30 has a wiring width not smaller than 0.1 μm. The fifth interlayer insulating film 28 is an insulating film formed mainly of a silicon oxide film.

A cap film 31 is formed on the fifth interlayer insulating film 28 and the fifth layer wiring 30. The cap film 31 is formed of, for example, a silicon nitride film or a silicon carbide film. The cap film 31 formed on the fifth interlayer insulating film 28 and the fifth layer wiring 30 acts both as the Cu diffusion suppressing film and the etching stopper like the cap film 23 described previously.

Further, a sixth interlayer insulating film 32 is formed on the cap film 31. A sixth layer wiring 34 covered with a barrier metal film 33 is formed in the sixth interlayer insulating film 32. The sixth layer wiring 34 is a damascene wiring. A barrier metal film 33 is formed on the inner surface of the wiring groove formed in the sixth interlayer insulating film 32. A Cu layer is buried in the wiring groove having the inner surface covered with the barrier metal film 33 so as to form the sixth layer wiring 34 noted above. Incidentally, the sixth layer wiring 34 has a wiring width not smaller than 0.1 μm. The sixth interlayer insulating film 32 is an insulating layer formed mainly of a silicon oxide film.

Further, a cap film 35 is formed on the sixth interlayer insulating film 32 and the sixth layer wiring 34. The cap film 35 is formed of, for example, a silicon nitride film or a silicon carbide film. The cap film 35 formed on the sixth interlayer insulating film 32 and the sixth layer wiring 34 is a film for preventing the diffusion of Cu forming the sixth layer wiring 34. As a result, formed is a semiconductor device having a multi-layered wiring structure including the first and second layer wirings (Ru wirings) 13, 16, and the third to sixth layer wirings (Cu wirings) 20, 26, 30 and 34.

The semiconductor device (LSI) according to the first embodiment of the present invention, which comprises the first to fifth layer wirings, was tested in an attempt to look into the relationship between the performance of the LSI and the change in the resistivity of the first layer wiring. The result of the performance deterioration simulation of the LSI will now be described.

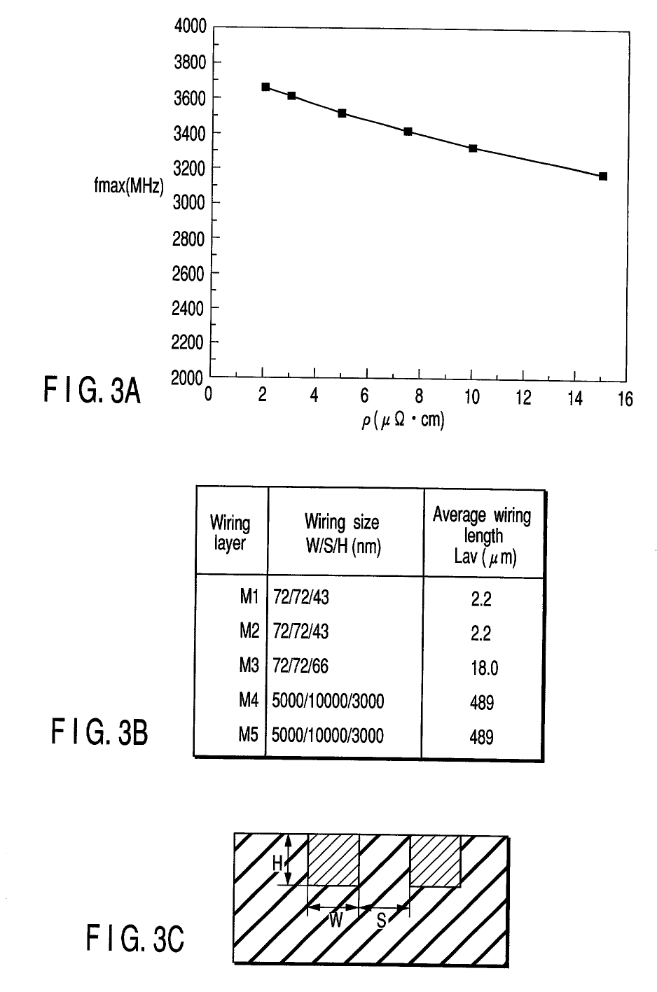

FIG. 3A is a graph showing the change in the LSI performance in the case of changing the resistivity of the first layer wiring in respect of the semiconductor device (LSI) according to the first embodiment of the present invention, which comprises the first to fifth layer wirings. In the graph of FIG. 3A, the resistivity ρ is plotted on the abscissa, with the operating maximum frequency fmax being plotted on the ordinate. FIG. 3B is a table showing the wiring size and the average wiring length of each wiring layer. M1 in FIG. 3B denotes a first layer wiring. Likewise, M2, M3, M4 and M5 denote the second layer wiring, the third layer wiring, the fourth layer wiring and the fifth layer wiring, respectively. Further, FIG. 3C is a cross sectional view showing the measuring points of the wiring size.

The performance deterioration of the LSI can be represented by the decrease in the operation maximum frequency. FIG. 3A shows that, if the performance deterioration of the LSI by 5% is allowable, i.e., if the operation maximum frequency fmax (MHz) by 5% is allowable, decrease in the resistivity of the wiring to about 10μ Ω·cm is allowable. It follows that it is possible to use a wiring material having a resistivity not lower than 10μ Ω·cm for forming the first layer wiring.

In the first embodiment of the present invention, ruthenium (Ru) was used as the wiring material of the first layer wiring. However, it is also possible to use another wiring material having a resistivity not higher than 10μ Ω·cm in place of Ru. For example, it also possible to use Al, Au, Ag, Nb, Ti or W for forming the first layer wiring. These wiring materials are used in the conventional semiconductor device and, thus, these wiring materials can be introduced into the manufacturing line relatively easily because the manufacturing apparatus of the semiconductor device can be commonly used and the contamination caused by these wiring materials can be dealt with easily.

In the wiring structure shown in FIG. 2, the lower layer wirings, i.e., the first and second layer wirings, are not covered with the barrier metal films. Therefore, even if the lower layer wiring is made finer, the ratio of the area occupied by the barrier metal film in the cross section of the lower layer wiring is not increased so as to make it possible to prevent the inconvenience that the wiring resistance is rapidly increased. Also, Ru has a resistivity higher than that of Cu. However, the average wiring length of the lower layer wiring is short in general among the multi-layered wiring. It follows that, even if Ru is used for forming the lower layer wiring, the wiring resistance is not appreciably increased, with the result that it is possible to suppress the increase in the resistance to a level at which the operating speed of the entire LSI is not affected. Incidentally, where Cu is used for forming the lower layer wiring, it is necessary to form a barrier metal film, leading to an increased ratio of the area occupied by the barrier metal film in the cross section of the wiring. It follows that the resistivity is rapidly increased so as to increase the wiring resistance.

As described above, the first embodiment of the present invention makes it possible to make the lower layer wiring finer so as to suppress the increase in the resistance of the wiring and the capacitance between the adjacent wirings.

Second Embodiment

As described above, it is necessary to use an etching stopper in the semiconductor device according to the first embodiment of the present invention, though it is unnecessary to use a diffusion suppressing film in the Ru wiring in each of the first and second layer wirings included. However, it is undesirable in some cases to use a silicon nitride film or a silicon carbide film as the etching stopper because each of the silicon nitride film and the silicon carbide film has a high dielectric constant. In the second embodiment of the present invention, a film having a low dielectric constant is used for forming the cap film (etching stopper film), and it is possible to ensure an etching selectivity ratio between the interlayer insulating film and the cap film.

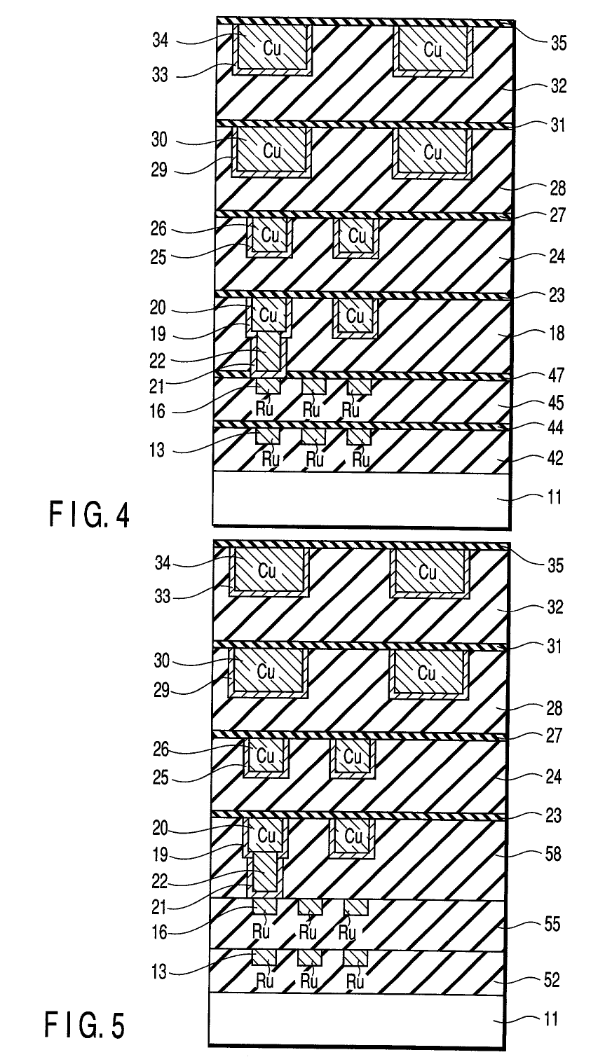

FIG. 4 is a cross sectional view showing the construction of a semiconductor device having a multi-layered wiring structure according to the second embodiment of the present invention.

It should be noted that each of cap films 44, 47 formed on the first layer wiring 13 and the second layer wiring 16, respectively, which are shown in FIG. 4, is formed of an insulating film containing polyarylene ether (PAE) as a main component and having a relative dielectric constant of about 2.7-3.1. Further, each of a first interlayer insulating film 42 and a second interlayer insulating film 45 formed on the first layer wiring 13 and the second layer wiring 16, respectively, is formed of an insulating material containing methyl-polysiloxane (MSX) as a main component and having a relative dielectric constant of about 2.8. In this case, it is possible to obtain an etching selectivity ratio of about 8 between the second interlayer insulating film 45 and the cap film 44 and an etching selectivity ratio of about 8 between the third interlayer insulating film 18 and the cap film 47. The second embodiment is equal to the first embodiment in the other construction.

In the construction according to the second embodiment of the present invention, a film having a low dielectric constant can be used for forming each of the interlayer insulating film and the cap film. In addition, it is possible to ensure an etching selectivity ratio between the interlayer insulating film and the cap film.

In the second embodiment of the present invention described above, it is possible to make the lower layer wiring finer without increasing the effective dielectric constant of the insulating film surrounding the lower layer wirings, i.e., the first layer wiring 13 and the second layer wiring 16, so as to suppress the increase in the resistance of the wiring and the capacitance between the adjacent wirings in the semiconductor device having a multi-layered wiring structure.

Third Embodiment

FIG. 5 is a cross sectional view showing the construction of a semiconductor device having a multi-layered wiring structure according to a third embodiment of the present invention.

As shown in FIG. 5, a first interlayer insulating film 52 consisting essentially of methyl-polysiloxane (MSX) is formed on the semiconductor substrate 11. Also, the first layer wiring (Ru wiring) 13, which is not covered with a barrier metal film, is formed in the first interlayer insulating film 52.

A second interlayer insulating film 55 consisting essentially of polyarylene ether (PAE) is formed on the first interlayer insulating film 52 and the first layer wiring 13. The second layer wiring (Ru wiring) 16, which is not covered with a barrier metal film, is formed in the second interlayer insulating film 55. Further, a third interlayer insulating film 58 consisting essentially of methyl-polysiloxane (MSX) is formed on the second interlayer insulating film 55 and the second layer wiring 16. The third embodiment is equal to the first embodiment in the other construction.

In the construction according to the third embodiment of the present invention, it is possible to ensure a sufficiently large selectivity ratio in the etching step between the second interlayer insulating film (polyarylene ether) and the first and third interlayer insulating films (methyl-polysiloxane). This makes it unnecessary to form a cap film on the upper surfaces of the first layer wiring 13 and the second layer wiring 16 as in the second embodiment. It follows that it is possible to use a film having a low dielectric constant for forming the interlayer insulating film and to ensure an etching selectivity ratio between the second interlayer insulating layer 55 and the first and third interlayer insulating films 52, 58.

As described above, according to the third embodiment of the present invention, it is possible to make the lower layer wiring finer without increasing the effective dielectric constant of the insulating film surrounding the lower layer wirings (the first layer wiring 13 and the second layer wiring 16) so as to suppress the increase in the resistance of the wiring and the capacitance between the adjacent wirings in a semiconductor device having a multi-layered wiring structure.

Fourth Embodiment

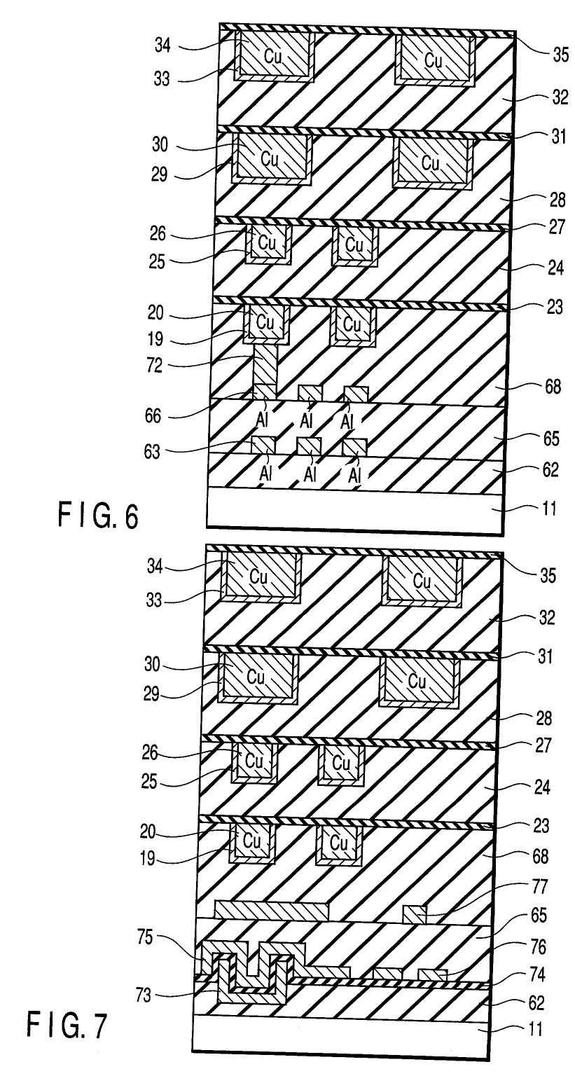

FIG. 6 is a cross sectional view showing the construction of a semiconductor device having a multi-layered wiring structure according to a fourth embodiment of the present invention.

As shown in FIG. 6, a first interlayer insulating film 62 consisting essentially of methyl-polysiloxane (MSX) is formed on the semiconductor substrate 11. A first layer wiring (Al wiring) 63, which is not covered with a barrier metal film, is formed on the first interlayer insulating film 62. The first layer wiring 63 is formed by depositing an Al film on the first interlayer insulating film 62, followed by selectively etching the Al film by, for example, a RIE method.

A second interlayer insulating film 65 consisting essentially of methyl-polysiloxane (MSX) is formed on the first interlayer insulating film 62 and the first layer wiring 63. A second layer wiring (Al wiring) 66, which is not covered with a barrier metal film, is formed on the second interlayer insulating film 65. The second layer wiring 66 is formed by depositing first an Al film on the second interlayer insulating film 65, followed by selectively etching the Al film thus deposited by, for example, a RIE method.

A third interlayer insulating film 68 consisting essentially of methyl-polysiloxane (MSX) is formed on the second interlayer insulating film 65 and the second layer wiring 66. Also, a third layer wiring 20 covered with the barrier metal film 19 is formed in the third interlayer insulating film 68. The third layer wiring 20 is a damascene wiring. The barrier metal film 19 is formed on the inner surface of a wiring groove formed in the third interlayer insulating film 68, and a Cu layer is buried in the wiring groove having the inner surface covered with the barrier metal film 19 so as to form the third layer wiring 20. A contact plug 72 is formed between the third layer wiring 20 and the second layer wiring 66 so as to electrically connect the third layer wiring 20 to the second layer wiring 66. The contact plug 72 is formed of tungsten (W).

The cap film 23 is formed on the third interlayer insulating film 68 and the third layer wiring 20. The cap film 23 is formed of, for example, a silicon nitride film or a silicon carbide film and acts as both the etching stopper film and the Cu diffusion suppressing film. The fourth embodiment of the present invention is equal to the first embodiment in the other construction.

As described above, according to the fourth embodiment of the present invention, it is possible to make the lower layer wiring finer without increasing the effective dielectric constant of the insulating film surrounding the lower layer wirings (the first layer wiring 63 and the second layer wiring 66) so as to suppress the increase in the resistance of the wiring and the capacitance between the adjacent wirings in a semiconductor device having a multi-layered wiring structure.

Fifth Embodiment

FIG. 7 is a cross sectional view showing the construction of a semiconductor device having a multi-layered wiring structure according to a fifth embodiment of the present invention.

As shown in FIG. 7, a first interlayer insulating film 62 consisting essentially of methyl-polysiloxane (MSX) is formed on the semiconductor substrate 11. A first electrode 73 forming one electrode of a capacitor is formed on the first interlayer insulating layer 62. Also, a second electrode 75 forming the other electrode of the capacitor noted above is formed on the first electrode 73 with a tantalum oxide film, e.g., a Ta₂o₅ film, 75 interposed therebetween. A first layer wiring (Ru wiring), which is not covered with a barrier metal film, is formed on that surface of the tantalum oxide film 74 on which is formed the second electrode 75. The first layer wiring 76 is formed by depositing first a Ru film on the tantalum oxide film 74, followed by selectively etching the Ru film by, for example, a RIE method. Each of the first electrode 73, the second electrode 75 and the first layer wiring 76 is formed of ruthenium (Ru).

A second interlayer insulating film 65 consisting essentially of methyl-polysiloxane (MSX) is formed on the tantalum oxide film 74, the second electrode 75 and the first layer wiring 76. Also, a second layer wiring (Ru wiring) 77, which is not covered with a barrier metal film, is formed on the second interlayer insulating film 65. The second layer wiring 77 is formed by depositing first a Ru film on the second interlayer insulating film 66, followed by selectively etching the Ru film by, for example, a RIE method.

Further, a third interlayer insulating film 68 consisting essentially of methyl-polysiloxane (MSX) is formed on the second interlayer insulating film 65 and the second layer wiring 77. The layer wiring 20 covered with the barrier metal film 19 is formed in the third interlayer insulating film 68.

Further, the cap film 23 is formed on the third interlayer insulating film 68 and the third layer wiring 20. The fifth embodiment of the present invention is equal to the first embodiment described previously in the other construction.

As described above, according to the fifth embodiment of the present invention, it is possible to make the lower layer wiring finer without increasing the effective dielectric constant of the insulating film surrounding the lower layer wirings (the first layer wiring 76 and the second layer wiring 77) so as to suppress the increase in the resistance of the wiring and the capacitance between the adjacent wirings in a semiconductor device having a multi-layered wiring structure. In addition, the lower layer wiring and the capacitor electrode can be formed on the same surface by using the same material. In other words, the lower layer electrode and the capacitor electrode can be formed by the same process so as to shorten the manufacturing process, which is advantageous in the manufacture of the semiconductor device.

Sixth Embodiment:

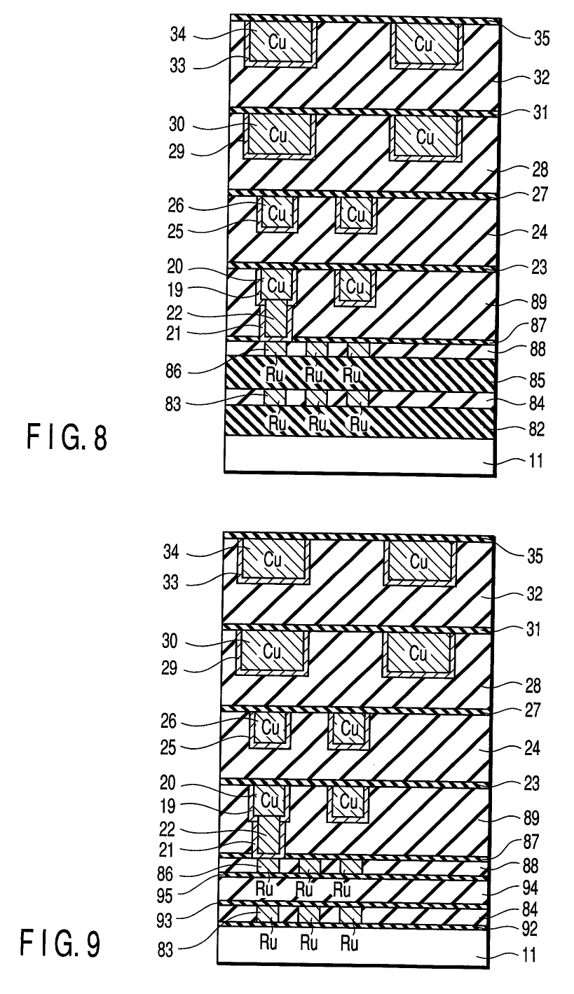

FIG. 8 is a cross sectional view showing the construction of a semiconductor device having a multi-layered wiring structure according to a sixth embodiment of the present invention.

As shown in FIG. 8, a first interlayer insulating film 82 consisting essentially of polyarylene ether (PAE) is formed on the semiconductor substrate 11. A first layer wiring (Ru wiring) 83, which is not covered with a barrier metal film, is formed on the first interlayer insulating film 82. An insulating film 84 consisting essentially of methyl-polysiloxane (MSX) is formed on the first interlayer insulating film 82 in a manner to be sandwiched between adjacent first layer wrings 83. The first layer wiring 83 is formed by depositing the insulating film 84 on the first interlayer insulating film 82, followed by forming a wiring groove in the insulating film 84 and subsequently burying a Ru layer in the wiring groove.

A second interlayer insulating film 85 consisting essentially of polyarylene ether (PAE) is formed on the insulating film (MSX) 84 and the first layer wiring 83. A second layer wiring (Ru wiring) 86, which is not covered with a barrier metal film, is formed on the second interlayer insulating film 85. Also, an insulating film 88 consisting essentially of methyl-polysiloxane (MSX) is formed on the second interlayer insulating film 85 so as to be sandwiched between adjacent second layer wirings 86. The second layer wiring 86 is formed by depositing first the insulating film 88 on the second interlayer insulating film 85, followed by forming a wiring groove in the insulating film 88 and subsequently burying a Ru layer in the wiring groove.

A cap film 87 consisting essentially of polyarylene ether (PAE) is formed on the insulating film (MSX) 88 and the second layer wiring 86. Further, a third interlayer insulating film 89 consisting essentially of methyl-polysiloxane (MSX) is formed on the cap film 87. The sixth embodiment of the present invention is equal to the first embodiment described previously in the other construction.

In the sixth embodiment of the present invention, the insulating film interposed between the adjacent lower layer wirings formed on the same layer and the interlayer insulating film formed between the lower layer wirings formed in different layers are formed of different materials.

As described above, according to the sixth embodiment of the present invention, it is possible to make the lower layer wiring finer without increasing the effective dielectric constant of the insulating film surrounding the lower layer wirings (the first layer wiring 83 and the second layer wiring 86) so as to suppress the increase in the resistance of the wiring and the capacitance between the adjacent wirings in a semiconductor device having a multi-layered wiring structure.

Seventh Embodiment

FIG. 9 is a cross sectional view showing the construction of a semiconductor device having a multi-layered wiring structure according to a seventh embodiment of the present invention.

As shown in FIG. 9, a first interlayer insulating film 92 consisting essentially of polyarylene ether (PAE) is formed on the semiconductor substrate 11. A first layer wiring (Ru wiring) 83, which is not covered with a barrier metal film, is formed on the first interlayer insulating film 92. An insulating film 84 consisting essentially of methyl-polysiloxane (MSX) is formed on the first interlayer insulating film 92 in a manner to be sandwiched between adjacent first layer wrings 83. The first layer wiring 83 is formed by depositing the insulating film 84 on the first interlayer insulating film 92, followed by forming a wiring groove in the insulating film 84 and subsequently burying a Ru layer in the wiring groove.

An insulating film 93 consisting essentially of polyarylene ether (PAE) is formed on the insulating film 84 and the first layer wiring 83, and an insulating film 94 consisting essentially of methyl-polysiloxane (MSX) is formed on the insulating film 93. Further, an insulating film 95 consisting essentially of polyarylene ether (PAE) is formed on the insulating film 94. These insulating films 93, 94 and 95 collectively form a second interlayer insulating film.

A second layer wiring (Ru wiring) 86, which is not covered with a barrier metal film, is formed on the insulating film 95, and an insulating film 88 consisting essentially of methyl-polysiloxane (MSX) is formed on the insulating film 95 so as to be interposed between adjacent second layer wiring 86. The second layer wiring 86 is formed by depositing first the insulating film 88 on the insulating film 95, followed by forming a wiring groove in the insulating film 88 and subsequently burying a Ru layer in the wiring groove.

A cap film 87 consisting essentially of polyarylene ether (PAE) is formed on the insulating film (MSX) 88 and the second layer wiring 86. Further, a third interlayer insulating film 89 consisting essentially of methyl-polysiloxane (MSX) is formed on the cap film 87. The seventh embodiment of the present invention equal to the first embodiment described previously in the other construction.

In the seventh embodiment of the present invention, the insulating film interposed between adjacent lower layer wirings formed in the same layer and the interlayer insulating film interposed between lower layer wirings formed in different layers are formed of different materials. Further, the interlayer insulating film is of a multi-layered structure consisting of a plurality of insulating films.

As described above, according to the seventh embodiment of the present invention, it is possible to make the lower layer wiring finer without increasing the effective dielectric constant of the insulating film surrounding the lower layer wirings (the first layer wiring 83 and the second layer wiring 86) so as to suppress the increase in the resistance of the wiring and the capacitance between the adjacent wirings in a semiconductor device having a multi-layered wiring structure.

In the semiconductor device having a multi-layered wiring structure according to the embodiments of the present invention, the lower layer wiring is formed of a wiring material having a diffusion coefficient smaller than that of Cu so as not to be diffused into the interlayer insulating film. In other words, a wiring material that makes it unnecessary to use a diffusion suppressing film is used forming the lower layer wiring. As a result, it is possible to prevent the ratio occupied by the barrier metal film in the cross section of the lower layer wiring from being increased in accordance with progress in the miniaturization of the lower layer wiring. It follows that it is possible to form a fine thin film wiring in a semiconductor device without bringing about the performance deterioration. Also, since it is unnecessary to take measures for preventing copper (Cu) from being diffused into the interlayer insulating film, it is unnecessary to use a silicon nitride film or a silicon carbide film, making it possible to form a multi-layered wiring structure by using only the films having a low dielectric constant.

It is necessary to select a material having a low resistivity as a material of the lower layer wiring. For example, the performance deterioration of the LSI is not brought about, if the resistivity of the material forming the lower layer wiring is not higher than 10μ Ω·cm.

Further, since it is unnecessary to form a silicon nitride film or a silicon carbide film, which produces a barrier effect against the Cu diffusion, in a manner to contact the lower layer wiring, the limitation that a film performing the function of a diffusion suppressing film must be formed is eliminated. It follows that it is possible to use a film having a relatively low dielectric constant for forming the insulating film surrounding the lower layer wiring. Presently, an interlayer insulating film consisting essentially of a silicon oxide film is formed so as not to be in direct contact with the copper layer. The interlayer insulating film of the particular type has a relative dielectric constant not higher than 4.1. In the present invention, however, the interlayer insulating film can be formed in direct contact with the wiring material so as to form a multi-layered wiring structure. It follows that it is possible to decrease the capacitance of the wiring.

What should also be noted is that the limitation to use a diffusion suppressing film can be eliminated if the insulating film is laminated in view of the etching selectivity ratio relative to the lower layer wiring so as to realize the structure that the lower layer wiring is covered with a plurality of films having a low dielectric constant. It follows that it is possible to increase the processing accuracy of the lower layer wiring and to lower the dielectric constant of the insulating film surrounding the lower layer wiring.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device, comprising:
a first interlayer insulating film formed on a semiconductor substrate;
a first wiring buried in said first interlayer insulating film in contact with the first interlayer insulating film;
a cap film formed on said first wiring;
a second interlayer insulating film formed on said cap film, a selectivity ratio being obtained between said second interlayer insulating film and said cap film in the etching step;
a second wiring buried in said second interlayer insulating film; and
a barrier metal film formed between said second wiring and said second interlayer insulating film and serving to prevent the material forming the second wiring from being diffused into the second interlayer insulating film.

2. The semiconductor device according to claim 1, further comprising a cap film formed on said second wiring and serving to prevent the material forming said second wiring from being diffused.

3. The semiconductor device according to claim 1, wherein the diffusion coefficient of the material forming said first wiring into said first interlayer insulating film is smaller than the diffusion coefficient of the material forming the second wiring into said second interlayer insulating film.

4. The semiconductor device according to claim 1, wherein the relative dielectric constant of each of said first interlayer insulating film and said cap film is smaller than the relative dielectric constant of a silicon oxide film.

5. The semiconductor device according to claim 1, wherein said first wiring is formed of a material selected from the group consisting of Ru, Al, Au, Ag, Nb, Ti and W.

6. The semiconductor device according to claim 5, wherein said second wiring is formed of Cu.

7. A semiconductor device, comprising:
a first interlayer insulating film formed on a semiconductor substrate;
a first wiring buried in said first interlayer insulating film in contact with said first interlayer insulating film;
a second interlayer insulating film formed on said first interlayer insulating film and said first wiring, a selectivity ratio being obtained between said second interlayer insulating film and said first interlayer insulating film in the etching step;
a second wiring buried in said second interlayer insulating film; and
a barrier metal film formed between said second wiring and said second interlayer insulating film, said barrier metal film serving to prevent the material forming said second wiring from being diffused into said second interlayer insulating film.

8. The semiconductor device according to claim 7, further comprising a cap film formed on said second wiring and serving to prevent the material forming said second wiring from being diffused.

9. The semiconductor device according to claim 7, wherein the diffusion coefficient of the material forming said first wiring into said first and second interlayer insulating films is smaller than the diffusion coefficient of the material forming the second wiring into said second interlayer insulating film.

10. The semiconductor device according to claim 7, wherein the relative dielectric constant of each of said first and second interlayer insulating films is smaller than the relative dielectric constant of a silicon oxide film.

11. The semiconductor device according to claim 7, wherein said first wiring is formed of a material selected from the group consisting of Ru, Al, Au, Ag, Nb, Ti and W.

12. The semiconductor device according to claim 11, wherein said second wiring is formed of Cu.

13. A semiconductor device, comprising:
a first interlayer insulating film formed on a semiconductor substrate;
a first wiring formed on said first interlayer insulating film;
a second interlayer insulating film formed on said first interlayer insulating film and said first wiring;
a second wiring buried in said second interlayer insulating film; and
a barrier metal film formed between said second wiring and said second interlayer insulating film and serving to prevent the material forming said second wiring from being diffused into said second interlayer insulating film.

14. The semiconductor device according to claim 13, further comprising a cap film formed on said second wiring and serving to prevent the material forming said second wiring from being diffused.

15. The semiconductor device according to claim 13, wherein the diffusion coefficient of the material forming said first wiring into said first and second interlayer insulating films is smaller than the diffusion coefficient of the material forming the second wiring into said second interlayer insulating film.

16. The semiconductor device according to claim 13, wherein the relative dielectric constant of each of said first and second interlayer insulating films is smaller than the relative dielectric constant of a silicon oxide film.

17. The semiconductor device according to claim 13, wherein said first wiring is formed of a material selected from the group consisting of Ru, Al, Au, Ag, Nb, Ti and W.

18. The semiconductor device according to claim 17, wherein said second wiring is formed of Cu.

19. A semiconductor device, comprising:
a first interlayer insulating film formed on a semiconductor substrate;
a second interlayer insulating film formed on said first interlayer insulating film;
a first wiring buried in said second interlayer insulating film, said first wiring having a lower surface facing the surface of said first interlayer insulating film, an upper surface facing said lower surface, and a side surface perpendicular to said lower surface and said upper surface, said lower surface being in contact with said first interlayer insulating film, and said side surface being in contact with said second interlayer insulating film;
a cap film formed on said upper surface of said first wiring and on said second interlayer insulating film;
a third interlayer insulating film formed on said cap film, a selectivity ratio being obtained between said third interlayer insulating film and said cap film in the etching step;
a second wiring buried in said third interlayer insulating film; and
a barrier metal film formed between said second wiring and said third interlayer insulating film and serving to prevent the material forming said second wiring from being diffused into said third interlayer insulating film.

20. The semiconductor device according to claim 19, further comprising a cap film formed on said second wiring and serving to prevent the material forming said second wiring from being diffused.

21. The semiconductor device according to claim 19, wherein the diffusion coefficient of the material forming said first wiring into said first and second interlayer insulating films and into said cap film is smaller than the diffusion coefficient of the material forming the second wiring into said third interlayer insulating film.

22. The semiconductor device according to claim 19, wherein the relative dielectric constant of each of said first and second interlayer insulating films and said cap film is smaller than the relative dielectric constant of a silicon oxide film.

23. The semiconductor device according to claim 19, wherein said first wiring is formed of a material selected from the group consisting of Ru, Al, Au, Ag, Nb, Ti and W.

24. The semiconductor device according to claim 23, wherein said second wiring contains Cu.
